(19) United States
(12) Patent Application Publication
(10) Pub. No.: US 2012/0112175 A1
(43) Pub. Date: May 10, 2012

(54) PHOTOVOLTAIC DEVICES COMPRISING ION PAIRS

(76) Inventors: Richard Friend, Cambridge cambridgeshire (GB); Justin Hodgkiss, Wellington (NZ); Wilheim Huck, Cambridge cambridgeshire (GB); Guoli Tu, Hubei (CN)

(21) Appl. No.: 13/318,161

(22) PCT Filed: Apr. 30, 2010
(86) PCT No.: PCT/GB2010/050726

§ 371 Date: Dec. 14, 2011

(30) Foreign Application Priority Data
Apr. 30, 2009 (GB) 0907445.1

(51) Int. Cl. H01L 51/00

(52) U.S. Cl. 257/40; 257/E51.024

(57) ABSTRACT

A photovoltaic (PV) device having an electron donor region and electron acceptor region, the donor and acceptor regions comprising conjugated polymers and/or molecular semiconductors, ion pairs being, preferably preferentially, located at, near or towards the interface between the donor and acceptor regions.

This invention relates to polymeric semiconductors and, in particular, although not exclusively, to polymeric semiconductors which are usable in photovoltaic or photoresponsive devices.

Semiconducting polymers make remarkably effective substitutes for conventional inorganic semiconductors in a range of optoelectronic devices including light emitting diodes (LEDs), photovoltaic (PV) diodes, field effect transistors (FETs), and lasers. Conjugated polymers offer considerable material advantages over inorganic semiconductors including chemically tunable optoelectronic properties and low-temperature, solution-based processing suitable for printed electronics. However, their additional functional potential has not been so widely recognized until recently. One functional advantage offered by conjugated polymers is their capacity to employ both electronic and ionic charge carriers in device operation. Whereas solid state inorganic semiconductors are typically impermeable and unstable towards extrinsic ions, ion transport is at the heart of energy conversion and signaling in the soft functional materials found in nature.

Benefits of using ionic charge carriers have been demonstrated in polymer light emitting devices (LEDs). In that case, efficient polymer LEDs have been fabricated by blending the active layer with electrolytes, or substituting it with single-component conjugated polyelectrolytes (CPEs) that have ion pairs tethered to the sidechains. The added ions were originally believed to facilitate electrochemical doping under applied bias, however mounting experimental evidence supports an electrodynamic model whereby the redistribution of mobile ions enhances the field locally at the electrodes, leading to facile and balanced electronic carrier injection. However, solid-state photoluminescence (PL) efficiencies of CPEs are found to be considerably lower than their neutral counterparts and dependent on the nature and size of counterions present. Accordingly, CPEs are deployed most effectively as thin injection layers between the electrodes and highly emissive neutral conjugated polymers. Extrinsic In³⁺ and Cl⁻ ions have also been found to induce PL quenching in films of neutral polymers without evidence of any electrochemical doping.

It is desirous to utilize the properties of CPEs in photoresponsive devices.

Polymer solar cells may comprise a layer or film of active layer, the donor layer, and a layer or film of acceptor molecules sandwiched between a pair of contacts. The donor layer may comprise conjugated polymer species which possess delocalized π electrons which can be excited by light (usually visible light) from the highest occupied molecular orbital (HOMO) to the molecules lowest unoccupied molecular orbital (LUMO), a π-π* transition. The band gap between the HOMO and LUMO corresponds to the energy of the light which can be absorbed.

In polymers the exciton electron-hole pairs created by such light absorption are strongly bound. However, the exciton pair can be dissociated by providing an interface across which the chemical potential of the electrons decreases. After dissociation, the electron will pass to the donor layer and be collected as a contact, whereas the hole will be collected by its respective contact. Of course, if the charge carrier mobility of either donor or acceptor layer is too low or not sufficiently high the charge carriers will not reach the contacts. For instance, the charge carriers may recombine at trap sites or remain in the respective layer or remain in the device as undesirable space charges that oppose the drift of new carriers.

A prior art polymer solar cell comprises a polyethylene teraphthalate (PET) substrate, upon which is provided successive layers of indium tin oxide (ITO), Poly(3,4-ethylenedioxythiophene)poly(styrenesulfonate) (PEDOT:PSS), an active layer which may be a polymer:fullerene blend, and an aluminium layer. In such a solar cell device architecture the polymer chain is the electron donor layer and fullerene is the electron acceptor layer.

It is a non-limiting object of the present invention to provide a new species for use in solar cells and a corresponding solar cell architecture which will, or may, lead to performance enhancements over prior art solar cell architectures.

Accordingly, a first aspect of the invention provides a photoresponsive device including a semiconducting polymer comprising redox inert ions.

The semiconducting polymer may be a copolymer.

A second aspect of the invention provides a solar cell having an electron donor region and electron acceptor region, the donor and acceptor regions comprising conjugated polymers, ion pairs being, preferably preferentially, located at, near or towards the interface between the donor and acceptor regions.

The cation and anion pairs may be located at either side of the interface or the cations one side and anions the other.

Further exploitation of ions in polymer optoelectronic devices will be enabled by better understanding the interactions between ions and electronic excitations, particularly the origin of the observed luminescence quenching. The difficulty of uncovering the inherent photophysical interactions arises, in part, because ions tethered to conjugated polymers introduce amphiphilic character which can induce rigid ordered backbone conformations and the formation of aggregates and interchain states. This prompted us to investigate the solid state photophysics of a derivative of poly(9,9′-dioctylfluorene-alt-benzothiadiazole) (F8BT) with a low density of ions that are tethered statistically. This arrangement was chosen to minimize the likelihood of ion-induced ordering while ensuring that ions are distributed with sufficient density to interact with electronic excitations in the film.

By time resolving emission and absorption spectra of excitons encountering ions in our CPE films, we show that, contrary to existing views, ions do not destroy optical excitations but rather induce the formation of long-lived, weakly emissive and immobile charge-transfer (CT) states via Coulombic interactions.

In order that the invention may be more fully understood, it will now be described, by way of example only, with reference to the accompanying drawings, in which:

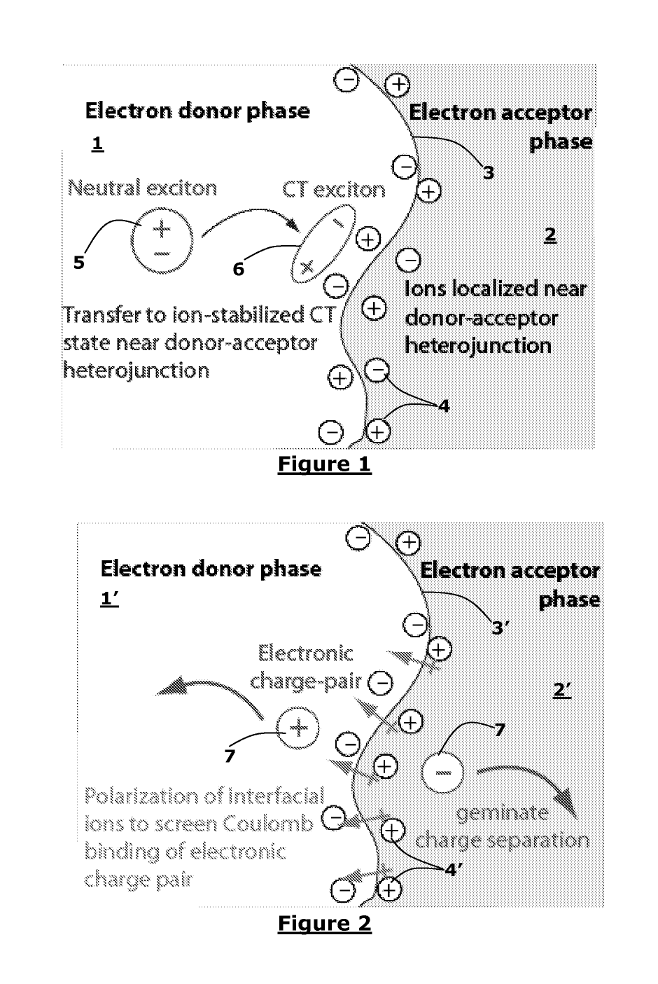

FIG. 1 is a schematic diagram of a first interface in a solar cell according to the invention;

FIG. 2 is a schematic diagram of a second interface in a solar cell according to the invention;

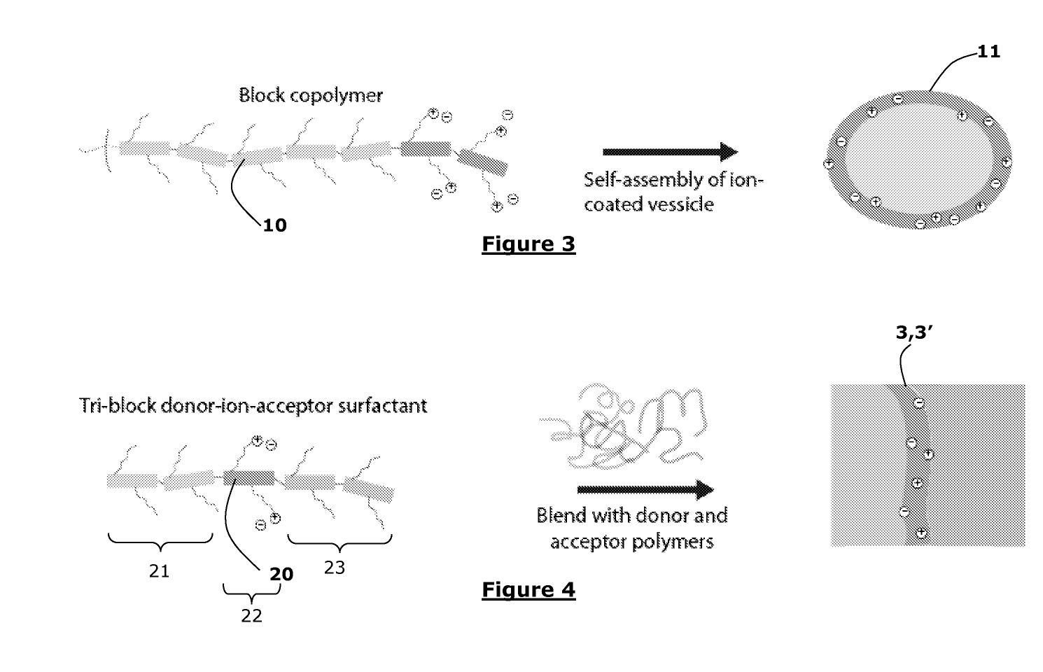

FIG. 3 is a schematic diagram of a first route to distribute ions at an interface;

FIG. 4 is a schematic diagram of a second route to distribute ions at an interface;

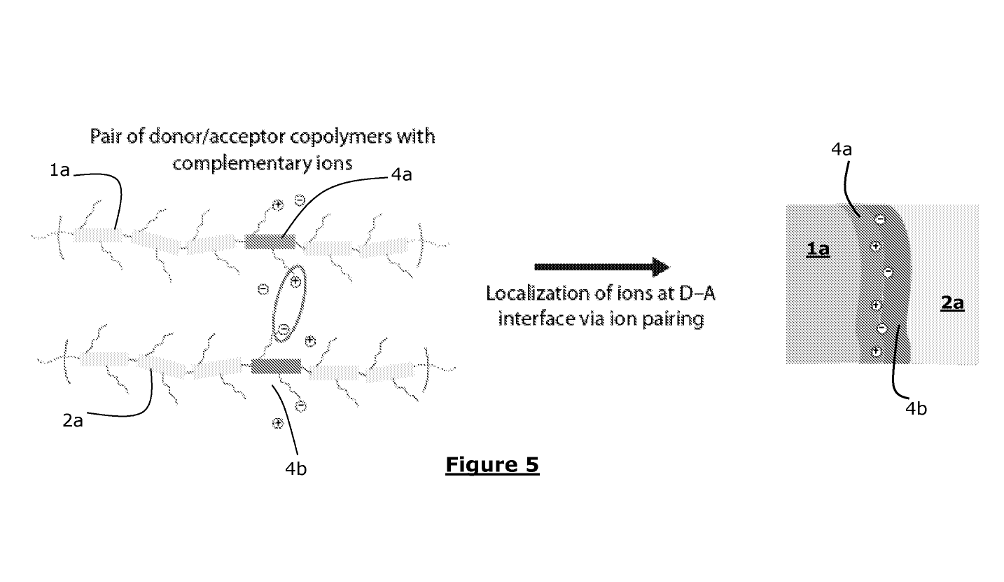

FIG. 5 is a schematic diagram of a third route to distribute ions at an interface;

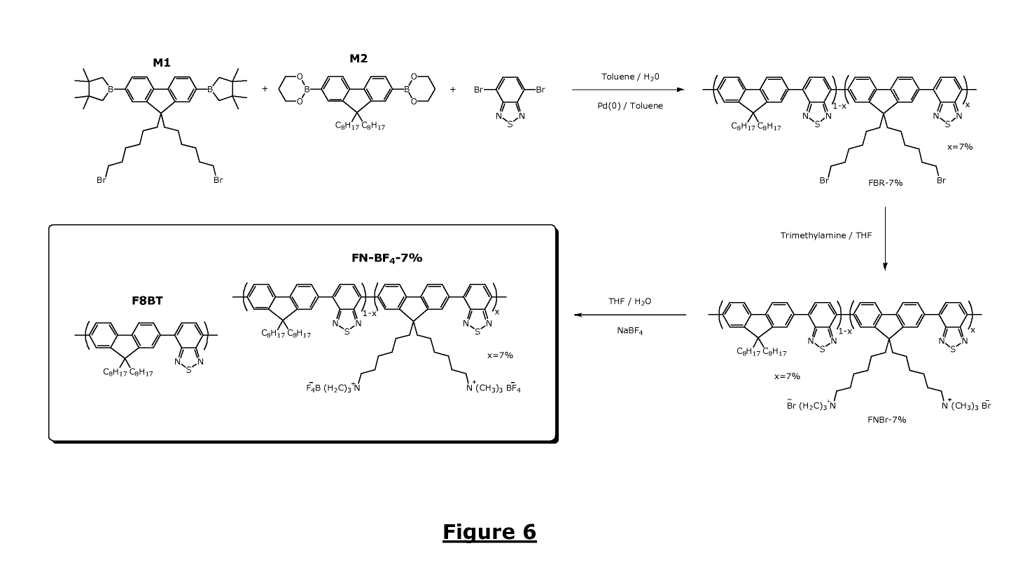

FIG. 6 is a reaction scheme according to the invention;

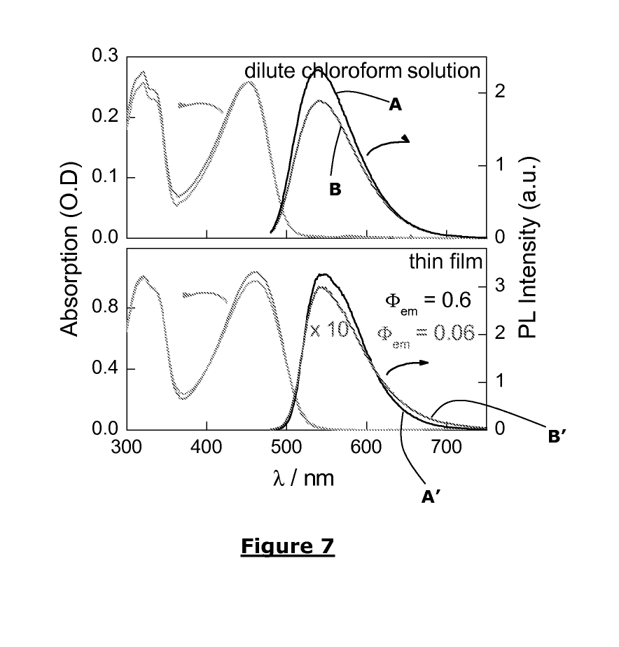

FIG. 7 shows optical absorption spectra and photoluminescence spectra of FN-BF₄-7% and F8BT (comparative example);

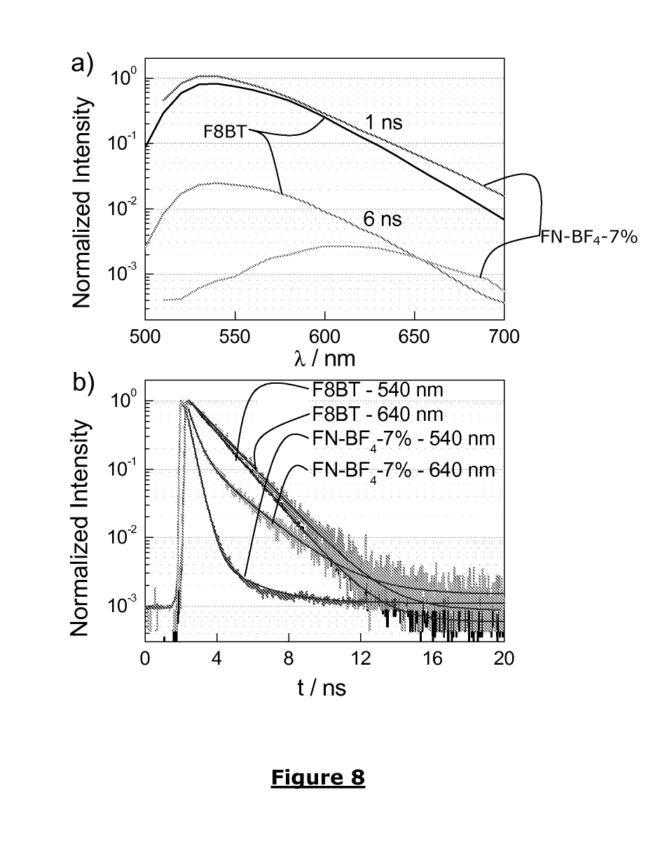

FIG. 8 shows a) time resolved photoluminescence spectra of F8BT (comparative example) and FN-BF4-7% at <1 ns and 6 ns after 470 nm excitation. b) Time-resolved PL kinetics for F8BT (comparative example) detected at 540 nm and 640 nm, and for FN-BF4-7% at the same wavelengths;

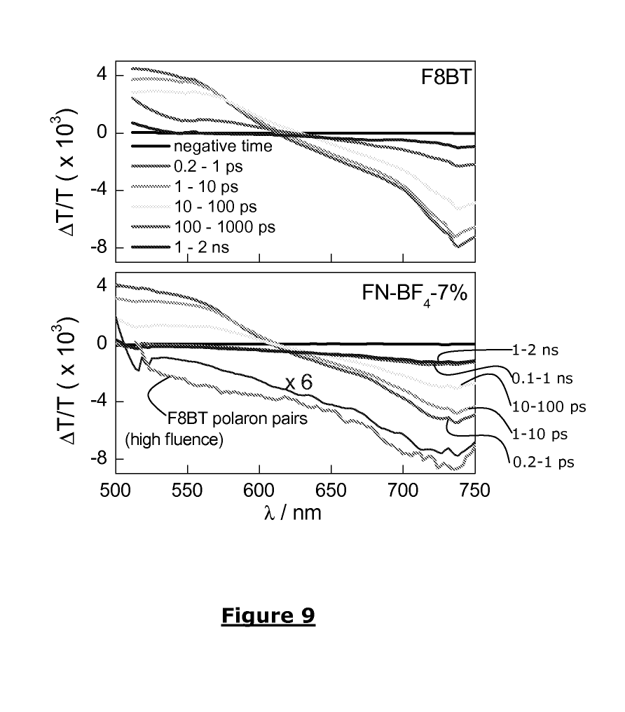

FIG. 9 shows transient absorption spectra of F8BT (top) and FN-BF₄-7% (bottom) within 2 ns of excitation with integrated time regions indicated (λ_{exc}=490 nm, fluence <10¹⁴ photons/cm²). The 1-2 ns spectrum is duplicated with a magnified scale in FN-BF₄-7% for better comparison with early time spectra. Also shown is the spectrum of F8BT polaron pairs formed via exciton annihilation under significantly (>25-fold) higher fluence;

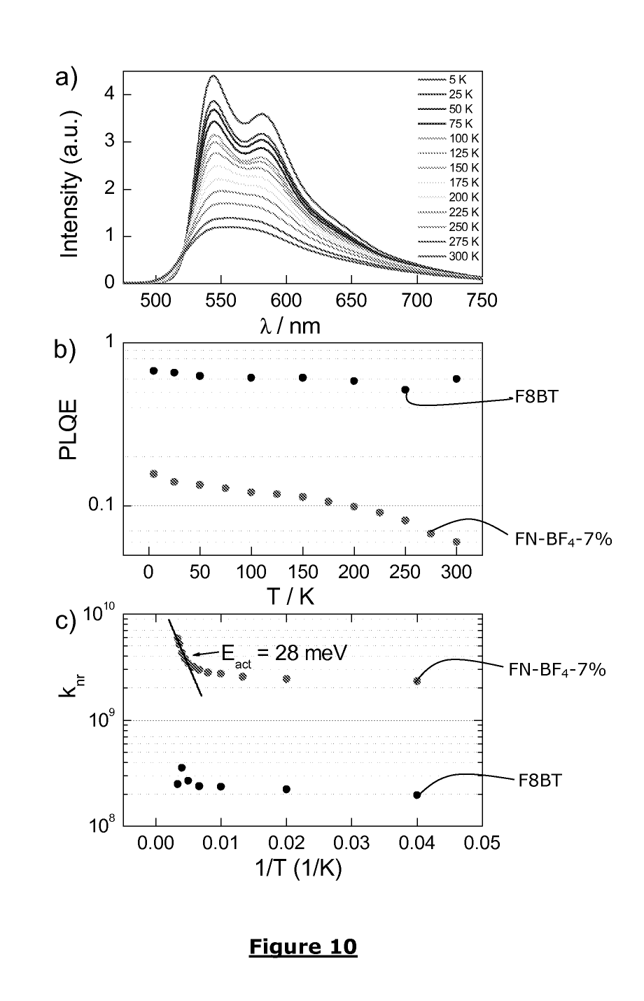

FIG. 10 shows a) temperature dependent PL spectra of FN-BF₄-7%. (λ_{exc}=470 nm); b) Temperature dependent PL Quantum efficiency (PLQE) of F8BT (comparative example) and FN-BF₄-7%; and c) Arrhenius plot of extracted non-radiative decay rate for F8BT (comparative example) and FN-BF₄-7%;

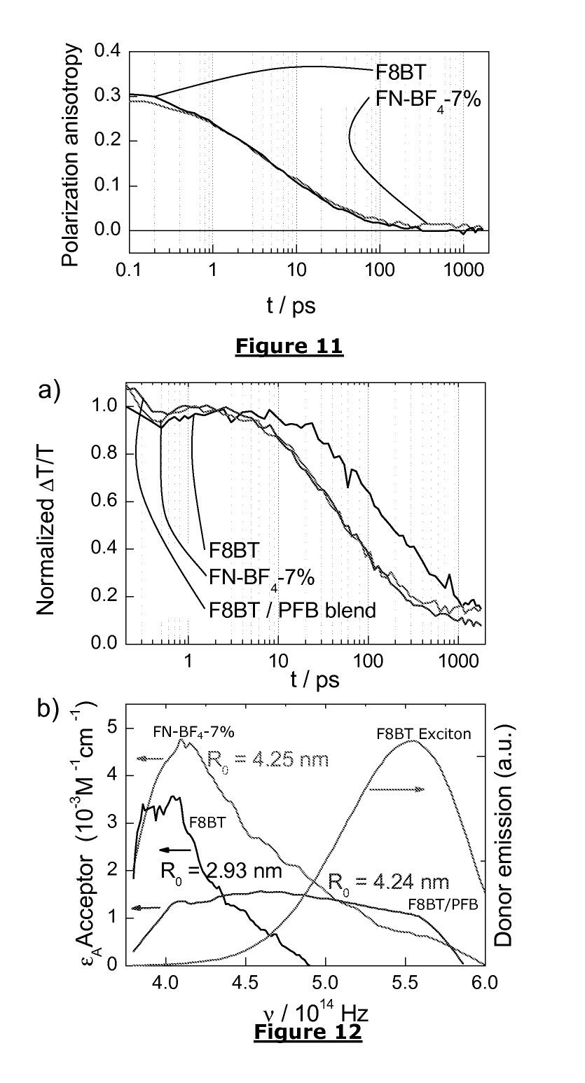

FIG. 11 shows transient absorption polarization anisotropy kinetics (λ_{exc}=490 nm, fluence<10¹⁴ photons/cm², λ_{probe}=800 nm) for F8BT (comparative example) and FN-BF4-7%.

FIG. 12 shows a) Normalized GS recovery kinetics for F8BT (comparative example), FN-BF₄-7% and an F8BT/PFB blend (comparative example) (λ_{exc}=490 nm, fluence=6×10¹³ photons/cm², λ_{probe}=490 nm). b) Relevant spectra to assess Förster transfer from an F8BT exciton donor to the following acceptors (with absorption shown in units of molar extinction coefficient); an F8BT exciton (comparative example), an FN-BF₄-7% charge pair and an F8BT/PFB charge pair (comparative example).

Referring first to FIG. 1, there is shown an interface 3 between an electron donor 1 and an acceptor 2 phase in a solar cell. It will be appreciated that ion pairs 4 are located at, adjacent or near to the donor-acceptor heterojunction 3.

A neutral, bound, exciton 5 generated in the donor phase 2 will migrate towards the ionic region at the interface 3 and is aligned with the ion pairs to generate a stable charge-transfer (CT) state 6.

It is considered that because CT states are stabilized by the Coulomb field of ions means that the strength of interaction with a neutral photoexcitation can be extrinsically tuned by varying the nature (i.e., size, valency) of the added ions. The screening of the electron-hole electrostatic attraction will facilitate separation of the electron hole pair.

Referring now to FIG. 2, there is shown an interface 3′ between an electron donor 1′ and an acceptor 2′ phase in a solar cell. It will be appreciated that ion pairs 4′ are located at, adjacent or near to the donor-acceptor heterojunction 3′. However, in this instance the cations and anions are distributed along respective sides of the interface.

Under the influence of an external bias, ions are displaced to some degree and thus redistribute the electric field across the active layer of the polymer solar cell. Again, ions are localized at the interface between donor 1′ and acceptor 2′ phases so that the electric field is enhanced at charge-separating interfaces where it can affect the dissociation of geminate charge pairs.

Ions 4′ at donor-acceptor interfaces 3′ are available to screen the mutual Coulomb attraction between photogenerated geminate electron-hole pairs 7, thus enhancing the likelihood of electronic charge-pairs escaping their binding radius and increasing the yield of free charges.

There are several ways to realize the intended ionic polymer solar cell architecture that localizes ion pairs 4, 4′ near the interfaces 3, 3′ between nanostructured donor 1, 1′ and acceptor 2, 2′ phases.

For example, and referring to FIG. 3, block copolymers 10 could template the phase separation between ionic and non-ionic regions during film formation, using the relative block lengths and solvent affinities to tune the phase morphology of the resulting vesicle 11. Such a block copolymer 10 could have a uniform conjugated backbone structure but separate blocks defined by the ion-pairs 4, 4′ tethered to the sidechains.

Alternatively, and referring to FIG. 4, a triblock oligomer 20 comprised of electron donor 1, 1′ and acceptor 2, 2′ blocks spanning an ionic unit (donor 21, ion 22, acceptor 23) could be blended with homopolymers of the respective donor 1, 1′ and acceptor 2, 2′. In this configuration, the oligomer 20 acts as a surfactant and localizes at the donor-acceptor interface 3, 3′, enabling the interface 3, 3′ to be engineered by the inclusion of ionic groups 4, 4′.

Additionally, and referring here to FIG. 5, donor is and acceptor 2a polymers could be designed to incorporate complementary ion pairs 4a, 4b into their structure that will be enriched at donor-acceptor interfaces 3, 3′ due to their favorable association of the ionically complementary species.

In order to further exemplify the invention, reference is made to the following non-limiting Example.

### EXAMPLE

Copolymerization of the bis(6-bromohexyl)-fluorenyl boronic ester M1 and the 9,9-dioctylfluorene boronic ester M2 with 4,7-dibromo-2,1,3-benzothiadiazol was achieved using palladium mediated Suzuki cross-coupling copolymerization (see Stork et al; Adv. Mater. 14 (2002) pp 361-366). The reaction route is outlined in FIG. 6.

NMR analysis of FNBr-7% revealed that a 1:9 M1:M2 feed ratio gave a copolymer containing 7% of the bis(6-bromohexyl)fluorine and 93% of F8BT repeats. The bromohexyl tails were treated with trimethylamine in THF to give the corresponding trimethylammonium derivatives with bromide counterions (FNBr-7%). The counter ions were then exchanged to tetrafluoroborate by dissolving the polymer in a THF and water solution containing an excess of NaBF₄. The solvent was then removed under reduced pressure, and the solid washed several times with deionized water to give the resulting polymer (FN-BF₄-7%) in 45% yield. The relatively low density of ionic sidechains in FN-BF₄-7% ensures that the polymer is soluble in most of the same solvents used to process F8BT.

FIG. 7 (top panel) shows the absorption and emission spectra of dilute choloroform solutions (10 mg/L) of FN-BF₄-7% (line B) compared with the non-ionic F8BT (line A). The spectral features are virtually identical. Moreover, time-resolved PL decays (not shown) are monoexponential and independent of wavelength, with nearly identical lifetimes for FN-BF₄-7% (τ=2.8 ns) and F8BT (τ=2.9 ns). The invariance of the photophysics indicates that the ionic sidechains and counterions do not interact with the conjugated backbone in dilute solution, nor do they induce aggregation or decomposition. Both effects have been found to lead to PL quenching in solutions of CPEs with exclusively ionic sidechains.

The bottom panel of FIG. 7 shows the absorption and emission spectra of thin films of FN-BF₄-7% (line B′) and F8BT (line A′). Again, the absorption spectra are virtually identical; however the PL intensity is significantly attenuated for the ionic copolymer FN-BF₄-7% compared with F8BT when measured under identical conditions. The integrated PL quantum efficiency is 6% for FN-BF₄-7% compared with 60% for F8BT. While the PL spectra are all peaked at λₑₘ=540 nm, comparison of the normalized PL spectra shows that FN-BF₄-7% has slightly enhanced emission on the red tail of the spectrum.

The observation of PL quenching and subtle spectral shifts prompted us to undertake time-resolved measurements by the time-correlated single photon counting (TCSPC) method in order to better understand the perturbations induced by the ions in thin films. FIG. 8a shows the time-resolved PL spectra for FN-BF₄-7% compared with F8BT. These spectra were obtained by reconstructing kinetic traces taken sequentially at 10-nm intervals throughout the spectrum. The F8BT PL decay kinetics (FIG. 8b) are well fit by single exponential functions, with little variation in lifetime across the spectrum (τ(540 nm)=1.41 ns, R²=0.999; τ(640 nm)=1.58 ns, R²=0.997), also evident by the invariance of the PL spectra at <1 ns and 6 ns following excitation. The exciton decay is dominated by radiative relaxation, and the minimal wavelength dependence shows that there is little energetic disorder sampled on the timescale of the measurement. In contrast to this, the FN-BF₄-7% spectra (FIG. 8a) exhibit strong quenching and a pronounced dynamic redshift. Within the first nanosecond after excitation, the PL spectrum (λₘₐₓ=540 nm) closely resembles the excitonic F8BT emission. However, this feature is rapidly quenched (τ=350±30 ps, approaching the 130-ps instrument response function), largely accounting for the 10-fold reduction in the integrated PL quantum efficiency. A secondary red-shifted emission peak (λₘₐₓ=610 nm) is clearly seen on longer timescales (τ=2.0±0.2 ns). The ions introduced in FN-BF₄-7% have the effect of quenching the primary exciton, while introducing a secondary emissive state that is stabilized by 0.3 eV with respect to the primary exciton. We note that spectral characteristics of the secondary red-shifted emission peak are reminiscent of the emissive interchain and intrachain CT states formed when F8BT is coupled with electron donors.

We turned to TA spectroscopy as a more direct probe of charge transfer (including non-emissive states), as shown in FIG. 9. For reference, the TA spectrum of F8BT (comparative example, top panel), is characterized by a stimulated emission (SE) feature (ΔT/T>0) at wavelengths corresponding to the PL (λ<610 nm), and a photoinduced absorption feature (ΔT/T<0) peaked at ˜740 nm that is associated with the red-shifted absorption of the exciton. Aside from the small Stokes shift in the stimulated emission, the decay is broadly wavelength independent and proceeds on the same timescale as GS recovery shown in FIG. 12a (we note that the signal is still decaying at the limit of our detection window). This is consistent with the simple decay of mobile emissive excitons to the ground state without the participation of any other intermediates, as has been shown in previous photophysical studies of F8BT at excitation intensities sufficiently low to avoid charge generation from exciton-exciton annihilation.

In the case of FN-BF₄-7% (FIG. 9, bottom panel) measured under identical low-fluence conditions, the exciton spectrum 1 ps after excitation is virtually identical to that of F8BT, consistent with the conclusion from time-resolved PL that the primary exciton is not affected by the presence of a low density of ions. However, the TA signal of FN-BF₄-7% ceases to evolve after a few hundred picoseconds, and the spectrum of the residual long-lived population is characterized by a broadened photoinduced absorption feature peaked at 700-750 nm that extends into the 500-600-nm region where stimulated emission is otherwise expected. These spectral features are consistent with charge photogeneration.

For comparison, the TA spectrum of charge pairs in pristine F8BT was independently obtained by exciting the sample with a significantly higher (>25-fold) fluence, known to produce polaron pairs via exciton-exciton annihilation. Indeed, the resulting high-fluence F8BT polaron pair TA spectrum shown in FIG. 9 has a broad visible absorption peaked at 730 nm and a lack of SE—strongly reminiscent of the long-lived TA signal measured in FN-BF₄-7% under low fluence.

Interchain and intrachain CT states derived from F8BT excitons coupled to electron-donating units have also been shown to give rise to weakened and red-shifted PL, longer radiative lifetimes, loss of SE, and broadened photoinduced absorption across the visible region. The TA and time-resolved PL spectra of FN-BF₄-7%, provide strong evidence that the added ions induce the photogeneration of CT states that have increased electron-hole separation compared with the emissive bound exciton. For brevity, our subsequent references to CT states will include both weakly emissive CT states and non-emissive polaron pairs.

Ionic charges have the potential to stabilize CT states in conjugated polymers by establishing local Coulomb fields that perturb the HOMO and LUMO orbital energies. For example, an anion will raise the energy levels of HOMO and LUMO orbitals of neighboring chains, thus attracting holes and repelling electrons, while a cation will have the reverse effect. The distribution of both anions and cations in the conjugated polymer film is thus expected to lead to local configurations where electron-hole pairs are separated under the influence of ions. The electronic structure of F8BT enhances the interaction with the Coulomb field of ions. The alternating fluorene (donor) and benzothiadiazole (acceptor) units give rise to CT character in the lowest energy excitonic states of F8BT, and consequently solvatochromism in the absorption and emission spectra.

In solid films of FN-BF₄-7%, CT excitons are stabilized when BF₄⁻ counter anions interact with a partially positive fluorene donor unit, whereas destabilization will occur if the BF₄⁻ ions interact with the partially negative benzothiadiazole (BT) units. Likewise, theoretical calculations show that quarternary amine cations attached to the polymer sidechains are poised to undergo electrostatic interaction with electronegative BT units.

We can also eliminate several other possible causes of exciton quenching in FN-BF₄-7%. Firstly, the quarternary amine and BF₄⁻ ions are not redox active towards F8BT in either the ground state or the singlet exciton state, thus limiting their role to a physical perturbation upon the polymer photophysics. Secondly, the absence of heavy atoms precludes the participation of triplet excited states because intersystem crossing operates on a timescale of ˜40 ns in F8BT. Thirdly, the photophysics observed in FN-BF₄-7% is not consistent with the presence of chemical keto defects—fluorenones that are found to appear as photo-oxidation products in some polyfluorenes. Fluorenone defects emit at significantly higher energy (λₘₐₓ˜540 nm) than the secondary emissive state we observe in FN-BF₄-7%, and are not considered to be important in fluorene copolymers such as F8BT with lower energy excited states. Additionally, spectroscopic measurements on solid films were carried out under vacuum (<10⁻⁵ Torr) to avoid the possibility of photo-oxidation.

Next we consider the possibility that tethered ions could induce conformational changes to the conjugated backbone, perhaps forming interchain aggregate states that act as recombination sites. Schwartz and coworkers (see Annu. Rev. Phys. Chem.; 54; pp 141-172 (2003)) have demonstrated that aggregates form when chains adopt extended conformations that permit close interchain contact, thus their formation depends strongly upon the nature of polymer sidechains and the solvent used for casting films. Aggregates display red-shifted absorption and emission spectra. As previously noted, the low density of tethered ions in FN-BF₄-7% and their statistical incorporation is not expected to cause significant ordering as it can in amphiphilic block copolymers or CPEs with ions attached to all sidechains. The invariance of GS absorption spectra and transient absorption polarization anisotropy decay strongly suggest that FN-BF₄-7% retains the same film morphology as F8BT. Additionally, previous studies that directly create and interrogate interchain interactions in F8BT provide little evidence that it could account for the photophysics observed in FN-BF₄-7%. It has been shown that thermal annealing increased the planarity of F8BT and changed the interchain packing from an eclipsed to an alternating packing structure with respect to F8 and BT units of adjacent chains (e.g. Donley et. al.; J. Am. Chem. Soc.; 127; pp 12890-12899 (2005))

Thermal annealing induced clear shifts in absorption and PL spectra, yet the corresponding ˜10% variation in PL efficiencies shows that such changes in conformation and chain packing are insufficient to explain the strong quenching we observe in FN-BF₄-7%. Schmidtke et. al. (Phys. Rev. Lett.; 99; pp 167401 (2007)) probed interchain interactions by carrying out photophysical studies on F8BT films under high pressures. Red-shifted absorption and PL spectra at pressures up to 5 GPa were actually explained mostly by the intramolecular planarization of F8BT chains, showing that even highly compressed chain conformations do not represent the photophysics of FN-BF₄-7%.

A low density of ions could not induce such a pronounced perturbation of exciton decay without invoking exciton migration towards ionic sites. This mechanism is exploited for the amplification of exciton quenching via charge- or energy transfer in sensors, since excitons diffuse in three dimensions to sample a relatively large volume for the presence of an analyte. In FN-BF₄-7%, two ion pairs are attached to the alkyl sidechains of 7% of monomer units in a statistical fashion, and the volume occupied by each monomer unit in a film is estimated to be ˜1.3 nm³ (based on the unit cell reported for F8BT films using x-ray diffraction techniques). Therefore, one would expect the mean distance between neighboring ion pairs to be ˜2.7 nm if the ion pairs are randomly dispersed throughout the film, which is certainly within the exciton diffusion radius of F8BT (>10 nm). Phase segregation between ionic and non-ionic regions could increase the size of pristine non-ionic regions, however the scope for phase segregation is expected to be rather constrained for a statistical copolymer with 7% ionic sidechains.

We undertook low temperature PL measurements in order to investigate the photophysical influence of dispersed ionic sites when exciton diffusion lengths are constrained due to insufficient energy for thermally activated exciton hopping. FIG. 10a shows the temperature dependence of PL in FN-BF₄-7%. In addition to the predicted sharpening of vibronic peaks, the PL intensity clearly undergoes a substantial increase with decreasing temperature; the integrated PLQE of FN-BF₄-7% increases nearly ˜3-fold upon lowering the temperature from 300 K to 5 K, whereas F8BT only exhibits a 1.1-fold increase in PLQE over this range (FIG. 10b), along with vibronic peak sharpening. FIG. 10c reformulates the PLQE data as an Arrhenius plot in order to examine the activation energy associated with exciton trapping. In this plot, it is assumed that non-radiative relaxation channels account for most of the variation in PLQE, thus kₙᵣ is extracted from each temperature in the series assuming that the radiative lifetime is equal for the two materials and independent of temperature (2.7 ns, based on the measured room temperature PLQE and lifetime of F8BT). While kₙᵣ is rather insensitive to temperature for F8BT, the ionic copolymer exhibits two distinct temperature regimes for variation in kₙᵣ, corresponding to activation energies of 28±4 meV (when fitting the range 200-300 K) and 0.1±0.03 meV (when fitting T<100 K). We do not attach any physical significance to the low energy component since it is lower than thermal energy, and likely to be susceptible to our assumption about the invariance of kᵣ. The 28-meV component accounts for most of the observed temperature variation of the PL intensity in FN-BF₄-7%, and we attribute this to the exciton hopping activation energy. The measured activation energy lies within the wide range of reported values e.g., 170 meV for singlet exciton hopping in PPV, 60 meV for triplet exciton hopping in a Platinum poly-yne, and 7 meV for triplet exciton hopping in an Ir(PPy)-cored dendrimer. In these examples, the activation energy for exciton motion is noted to be very sensitive to the nature and strength of intermolecular interactions and the energetic disorder. The variable temperature measurements do not reveal the activation energy for exciton hopping in pristine F8BT due to the absence of quenching sites. Even at low temperature, the PLQE is considerably (˜3.5-fold) lower for FN-BF₄-7% than for non-ionic F8BT, indicating that exciton diffusion is not completely shut off at low temperature. Simple geometric considerations suggest that the exciton diffusion radius of FN-BF₄-7% decreases by a factor of 1.44 in going from 300 K to 5 K. This is consistent with the ˜1.5-fold contraction of the exciton diffusion radius reported for MEH-PPV at low temperature, where a temperature-independent exciton transfer regime persists.

Polarization anisotropy dynamics are a powerful probe of exciton motion in disordered chromophore materials. FIG. 11 shows polarization resolved transient absorption (TA) kinetics for FN-BF₄-7% compared with F8BT (comparative example) probed in the photoinduced absorption region at 800 nm (vide infra). The polarization anisotropy decays with a time constant of ˜8 ps in both materials, which corresponds to depolarization of excitons in just a few hops—significantly shorter than the timescale of exciton population decay (vide infra). The similarity of polarization anisotropy decays indicates that the ionic subsituents do not significantly alter the film morphology in FN-BF₄-7% compared with F8BT. Additionally, the initial polarization anisotropy levels (r˜0.3) are sufficiently high to suggest that there is negligible absorption into interchain aggregate states, which has been demonstrated cause depolarization on an ultrafast timescale. However, the polarization anisotropy does not quite decay to a zero baseline in FN-BF₄-7% as it does in F8BT. The non-zero anisotropy baseline corresponds to the residual population of long-lived excitations in the ionic copolymer, leading us to conclude that the residual population is immobile. The small magnitude of long-lived anisotropy is simply a consequence of rapid depolarization during the exciton hopping steps prior to trapping, thus only the fraction of excitons that were trapped in CT states within the first few hops are expected to retain polarization anisotropy.

Finally, we sought to quantify the fraction of excitations that form long-lived CT states (rather than decaying to the GS) by measuring the GS recovery kinetics by at a wavelength (λ_{probe}=490 nm) that is resonant with the GS absorption band and too high in energy to induce excited state absorption or stimulated emission. FIG. 12a shows the normalized kinetics of GS recovery for FN-BF₄-7% and F8BT. Low excitation fluences (6×10¹³ ph/cm²) were used to preclude the effect of exciton-exciton interactions. When considering the first 400 ps of the kinetics trace, the ionic copolymer undergoes significantly faster GS recovery compared with F8BT. Beyond this time, a residual signal is retained out to the maximum time delay of 1.7 ns, whereas the F8BT continues to proceed toward complete GS recovery. The residual signal in FN-BF₄-7% corresponds to ˜15% of the initial excited state population. This result appears to imply that the presence of ions primarily accelerates the decay of most excitons to the ground state non-radiatively, with only small residual (<15%) trapped as CT states to contribute to the red-shifted emission and transient absorption signal. However, we see no plausible mechanism that could readily account for such rapid non-radiative decay of excitons, as required to reconcile the picosecond GS recovery kinetics with the low steady-state PLQE in the presence of redox-inert ions.

Instead, we consider whether excitons could be quenched by prior photogenerated charges at the excitation intensities used in the TA measurements. Singlet excitons are known to be efficiently quenched by polarons in conjugated organic materials, typically via Förster resonant energy transfer from an emissive exciton to an absorbing polaron. The enhanced visible absorption of charges relative to excitons means that this bimolecular decay channel can still be operative at excitation densities below the threshold of exciton-exciton annhiliation. We calculated the Förster radius for resonant energy transfer from an F8BT exciton to an absorbing CT state. According to the application of Förster theory to conjugated polymers, the Förster radius (R₀) is given by;

$${R}_{0}^{6} = \frac{9 {Q}_{0} ( ln 10 ) {κ}^{2}}{128 {π}^{5} {η}^{4} {N}_{AV}} {\int }_{ }^{ } {f}_{D} ( λ ) {ɛ}_{A} ( λ ) {λ}^{4} d λ \qquad ( 1 )$$

In equation 1, κ² is the orientational factor (taken to be 0.655 for the case where the donor and acceptor dipoles lie in the plane of the film) η is the refractive index of the medium (previously measured to be 1.8 by ellipsometry), N_{Av} is Avagadro's number, f_{D}(λ) is the emission spectrum of the donor (in this case an F8BT singlet exciton) normalized such that ∫f_{D}(λ) d v=1, and ε_{A}(λ) is the absorption spectrum of the acceptor (the CT state in this case) in units of molar extinction coefficient (M⁻¹ cm⁻¹). The absorption spectrum is obtained in the appropriate units using;

$${ɛ}_{A} ( λ ) = \frac{{log}_{10} e}{1000} {N}_{AV} σ ( λ ) \qquad ( 2 )$$

where σ(λ) is the absorption cross-section calculated from the transient transmission spectrum using;

$$σ ( λ ) = \frac{1}{N} ln 1 + \frac{Δ T}{T} λ \qquad ( 3 )$$

In equation 3, the excitation density (N=4.7×10¹⁷ cm⁻³) is determined from the product of the incident fluence (6×10¹³ ph/cm²), the absorption efficiency at the excitation wavelength (η_{490 nm}=0.78), the fraction of excitions that survive beyond 1 ns where the spectrum is measured (Φ=0.15, based in the red curve in FIG. 12a), and the film thickness (z=150 nm). A strong Förster overlap for quenching by CT states is evident in FIG. 12b, corresponding to a Förster radius of 4.25 nm. This is considerably higher than the corresponding radius for quenching by another F8BT exciton (2.93 nm, black curve), corresponding to a 10-fold enhancement in the Förster transfer rate when the ratio is taken to the sixth power according to the Förster equation. It is clear from FIG. 12b that the loss of SE and the extension of absorption into the PL region accounts for the enhanced Förster quenching by CT states. At the excitation densities employed for the TA studies, the mean distance between initial excitations (r=³√(1/N₀)=6.9 nm approaches the calculated Förster radius, indicating that photogenerated CT states in FN-BF₄-7% are indeed likely to rapidly quench nearby excitons at the fluences used. We note that comparing the Förster radius to the mean distance between excitations is overly simplistic for many reasons, including; i) the distribution of excitations is neither uniform nor static on the timescale of quenching (as demonstrated by the temperature dependent PL and the 8-ps exciton depolarization), ii) an exciton can undergo multiple pairwise interactions with quenching sites in a film, resulting in a cumulative quenching rate, iii) the point-dipole model that underpins Förster theory breaks down for the closely packed arrays of elongated chromophores encountered in conjugated polymers, and iv) additional (non-resonant) mechanisms could also contribute to charge-induced exciton quenching. Taking these corrections into account will enhance the predicted rate of exciton quenching by CT states.

Rather than attempting to quantify these corrections, we measured GS recovery kinetics under identical conditions for F8BT blended with PFB (poly(9,9-dioctylfluorene-co-bis-N,N″-(4,butylphenyl)-bis-N,N″-phenyl-1,4-phenylene-diamine), a combination that is known to readily facilitate charge photogeneration and photovoltaic behavior. We were able to prepare a blended film morphology that exhibited F8BT exciton quenching on a comparable timescale to FN-BF₄-7% by casting the film (1:1 F8BT:PFB by weight) from a mixture of low- and high-boiling-point solvents, in this case chloroform:chlorobenzene (90:10 by volume). The conversion of excitons to long-lived charge-pairs is known to be very efficient in this blend under steady state excitation (Φ_{excition→charge}>60%).

Therefore, if no additional quenching channels were operational, one would expect the blend to exhibit GS recovery kinetics similar to unblended F8BT, but with the decay arrested at >0.6 of the initial level corresponding to the charge population. However, we observe that the GS recovery kinetics are markedly accelerated in the blend and only <10% of excitations survive 2 ns after the excitation pulse (FIG. 12a, blue curve). FIG. 12a is taken as strong evidence that excitons are quenched by prior photogenerated charges in both the ionic polymer FN-BF₄-7%, and the donor-acceptor blend at fluences below the threshold for exciton-exciton annihilation. Accordingly, FIG. 12c shows that the overlap integral for Förster quenching via interfacial charge-pairs in the F8BT:PFB blend (R₀=4.24 nm) is nearly identical to that of the CT state in FN-BF₄-7% (R₀=4.25 nm). Exciton quenching by photogenerated charges under pulsed excitation in FN-BF₄-7% causes us to underestimate the fraction of excitons that form CT states under steady state conditions. Comparison with GS recovery kinetics in the donor-acceptor blend implies that under steady state excitation, ions will induce the majority of excitons to convert to CT states in the CPE, potentially accounting for all of the observed PL quenching.

We have synthesized a CPE with a low density ionic sidechains and applied time-resolved spectroscopy techniques in order to isolate the inherent interactions between excitons and ionic charges in CPE films. Without wishing to be bound by any particular theory, we believe that time-resolved emission and absorption spectroscopy show that in films of FN-BF₄-7%, the primary exciton resembles that of the non-ionic counterpart (F8BT). Excitons then undergo activated hopping (E_{act}=28 meV) until the majority encounter a region where ions interact with the polymer backbone in FN-BF₄-7%. Beyond this timescale, the excited state population exhibits longer-lived emission that is stabilized by 0.3 eV, loss of stimulated emission, and a broadened photo-induced absorption signal. These spectral features provide strong evidence for photogenerated CT states induced by the interaction of ions with bound excitons in CPEs.

These findings have significant implications for the design of conjugated polymer devices that incorporate ionic charge carriers. Unless the interaction between ions and conjugated polymer backbone is well-controlled, morphologies must be optimized to exclude ions from exciton transporting domains. In the case of LEDs, it is notable that ions are most effectively deployed as a layer that is well-separated from the recombination zone where emissive excitons are generated.

Producing a favorable morphology that exploits mobile ionic charges to assist electronic charge separation in bulk heterojunction polymer PV devices is more challenging. Here, ions must be distributed on the nanometer lengthscale at donor-acceptor interfaces throughout the active layer in order to assist charge separation, whilst being excluded from within exciton transporting domains. Our data demonstrates that excitons are effectively funneled towards ionic regions, thereby allowing us to direct the motion of excitons by controlling the spatial distribution of ions and their interaction strengths. We note that counter ions could be readily substituted in order to tune the energetic balance between excitons and separated charges in CPEs.

Accordingly, the presented data demonstrates that CPE with low density ionic sidechains are eminently usable in PV devices and that the presence of ions at the interface between donor and acceptor layers can lead to improved performance of such devices.

It will be readily appreciated by the skilled person, that other ionic species may be incorporated into the polymeric structure. It will be further appreciated that other CPEs and molecular semiconductors (e.g. fullerenes) may be used in the invention outlined herein.

It will be further appreciated that one or both of the species may have tethered ions as discussed above.

1.-27. (canceled)

28. A photovoltaic (PV) device having an electron donor region and electron acceptor region, the donor and acceptor regions comprising conjugated polymers and/or molecular semiconductors, with ion pairs being located at, near or towards an interface between the donor and acceptor regions.

29. A PV device according to claim 28, wherein cation and anion pairs are located towards or at either side of the interface or cations are on one side of the interface and anions are towards or on the other side of the interface.

30. A PV device according to claim 28, wherein the ion pairs are provided on, tethered to, or as side chains to at least one of the conjugated polymers and/or at least one of the molecular semiconductors.

31. A PV device according to claim 28, wherein the conjugated polymers comprise a donor conjugated polymer and an acceptor conjugated polymer, and at least one of the donor conjugated polymer and the acceptor conjugated polymer is a copolymer.

32. A PV device according to claim 31, wherein the copolymer comprises an ionic unit and a non-ionic unit.

33. A PV device according to claim 32, wherein the ionic unit provides a minor proportion of the copolymer.

34. A PV device according to claim 32, wherein the ionic unit comprises less than 40% of the copolymer.

35. A PV device according to claim 34, wherein the ionic unit comprises from 0.001 to 9.999% of the copolymer.

36. A PV device according to claim 28, wherein the ion pairs are redox inert ions.

37. A PV device according to claim 28, comprising a polymer of the form:
[CP₁]₁₋ₓ[CP₂(R₁(A₁B₁))]ₓ
where CP₁ and CP₂ are conjugated polymers;
R₁ is an alkyl group of C₂-C₁₈; and
A₁B₁ are together an ion pair.

38. A PV device according to claim 28, comprising a polymer of the form:
[CP₁]₁₋ₓ[CP₂(R₁(A₁B₁) R₂(A₂B₂))]ₓ
where CP₁ and CP₂ are the same or different conjugated polymers;
R₁ and R₂ are the same or different alkyl or substituted groups of C₂-C₂₀;
A₁B₁ are together an ion pair; and
A₂B₂ are together an ion pair.

39. A PV device according to claim 28, comprising: 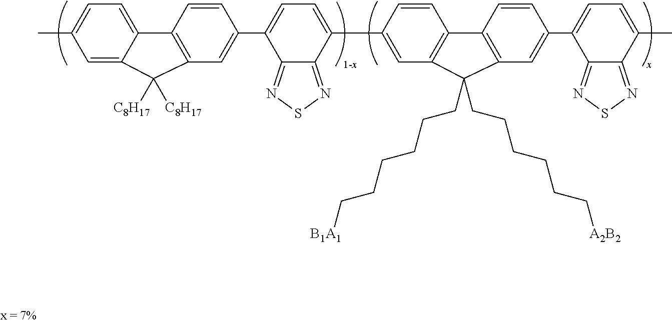
where A₁B₁ and A₂B₂ are together an ion pair.

40. A PV device according to claim 38, wherein A₁B₁ and A₂B₂ are the same.

41. A PV device according to claim 28, comprising:

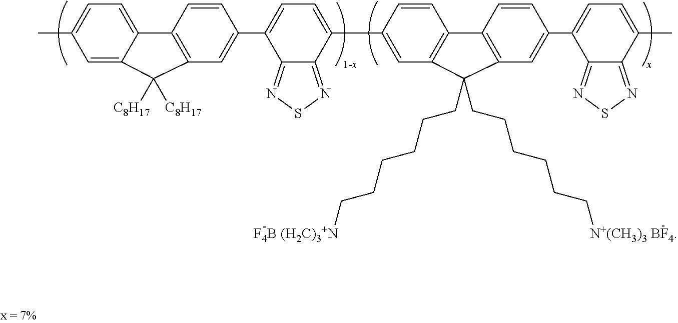

42. A PV device according to claim 28, wherein the interface between donor and acceptor regions is formed from or comprises a tri-block oligomer comprising donor and acceptor blocks.

43. A PV device according to claim 28, wherein the interface between donor and acceptor regions is formed from or comprises donor and acceptor polymers having respective complementary ion pairs.

44. A method of providing ions at an interface of donor and acceptor regions in a PV device, the method comprising blending an n-block oligomer having donor and acceptor blocks with homopolymers of the respective donor and acceptor blocks.

45. A polymer for a PV device, the polymer selected from the group consisting of:
[CP₁]₁₋ₓ[CP₂(R₁(A₁B₁))]ₓ (a)
where CP₁ and CP₂ are the same or different conjugated polymers;
R₁ is an alkyl group of C₂-C₂₀; and
A₁B₁ are together an ion pair; and
[CP₁]₁₋ₓ[CP₂(R₁(A₁B₁) R₂(A₂B₂))]ₓ (b)
where CP₁ and CP₂ are the same or different conjugated polymers;
R₁ and R₂ are the same or different alkyl or substituted alkyl groups of C₂-C₂₀;
A₁B₁ are together an ion pair; and
A₂B₂ are together an ion pair.
